(19) United States
(12) Patent Application Publication
(10) Pub. No.: US 2015/0243707 A1
(43) Pub. Date: Aug. 27, 2015

(54) TUNNELING TRANSISTOR HAVING A VERTICAL CHANNEL, VARIABLE RESISTIVE MEMORY DEVICE INCLUDING THE SAME, AND METHOD FOR MANUFACTURING THE SAME

(71) Applicant: SK hynix Inc., Gyeonggi-do (KR)

(72) Inventor: Nam Kyun PARK, Gyeonggi-do (KR)

(21) Appl. No.: 14/297,291

(22) Filed: Jun. 5, 2014

(30) Foreign Application Priority Data
Feb. 27, 2014 (KR) 10-2014-0023366

(51) Int. Cl. H01L 27/24; H01L 29/66; H01L 29/78

(52) U.S. Cl. CPC H01L 27/2454; H01L 29/7827; H01L 29/66666

(57) ABSTRACT

A tunneling transistor including a semiconductor substrate on which a source is formed in an upper region and having a first semiconductor material layer, a pillar formed on the semiconductor substrate and having a structure in which a channel layer and a drain are sequentially stacked, a gate formed to surround a circumference of the pillar, and a second semiconductor material layer constituting a portion of the source, formed between the source and the channel layer, having the same conductivity type as the source, and having a band gap smaller than the first semiconductor material layer. Wherein, the source and the drain have opposite conductivity types.

### CROSS-REFERENCES TO RELATED APPLICATION

This application claims priority under 35 U.S.C. 119(a) to Korean application No. 10-2014-0023366, filed on Feb. 27, 2014, which is herein incorporated by reference in its entirety.

### BACKGROUND

1. Technical Field

Various embodiments of the present invention generally relate to a semiconductor device and a method for manufacturing the same, and more particularly, to a tunneling transistor, a variable resistive memory device including the same, and a method for manufacturing the same.

2. Related Art

With the rapid development of mobile and digital information communication and the consumer-electronics industry, studies on existing electronic charge controlled-devices have disclosed limitations. Thus, new functional memory devices applying novel concepts need to be developed. In particular, next-generation memory devices with large capacities, ultra-high speed, and ultra-low power need to be developed to satisfy demands for large capacity memories.

Variable resistive memory devices that use a resistance material as a memory medium have been suggested as the next-generation memory devices. Typical examples of variable resistive memory devices are phase-change random access memories (PCRAMs), resistance RAMs (ReRAMs), or magnetic RAMs (MRAMs).

Typically, a variable resistive memory device may be formed using a switching device and a resistance device, and may store data such as “0” or “1,” according to the state of the resistance device

Even in variable resistive memory devices, the first priority is to improve integration density and to integrate as many memory cells as possible into a limited area.

To meet demand, three-dimensional (3D) transistor structures are also employed in resistive memory devices. Thus, a 3D transistor may include a channel extending in a direction perpendicular to the surface of a semiconductor substrate with a gate formed to surround the channel.

It is necessary to provide high operation current to the 3D transistor to maintain high resistance variable characteristics.

### SUMMARY

According to an embodiment of the present invention, a tunneling transistor may include a semiconductor substrate having a source formed in an upper region and includes a first semiconductor material layer, a pillar formed on the semiconductor substrate, a channel layer and a drain that are sequentially stacked, a gate formed to surround a circumference of the pillar, and a second semiconductor material layer constituting a portion of the source, formed between the source and the channel layer, having the same conductivity type as the source, and having a band gap smaller than the first semiconductor material layer. The source and the drain may have opposite conductivity types from each other.

According to an embodiment of the present invention, a variable resistive memory device may include a semiconductor substrate having a source formed in an upper region and includes a first semiconductor material layer, a pillar formed on a semiconductor in substrate and having a channel layer and a drain containing dopants having an opposite conductivity type to the source that are sequentially stacked, a gate formed to surround a circumference of the pillar, a second semiconductor material layer constituting a portion of the source, formed between the source and the channel layer, having the same conductivity type as the source, and having a band gap smaller than the first semiconductor material layer, a heating electrode formed on the drain, and a variable resistive layer formed on the heating electrode.

According to an embodiment of the present invention, a method of fabricating a tunneling transistor may include forming a source including a second semiconductor material layer having a band gap smaller than a first semiconductor material layer on a semiconductor substrate including the first semiconductor material layer, sequentially stacking a channel layer and a drain on the semiconductor substrate, forming a pillar including the channel layer and the drain, forming a gate insulating layer on a surface of the pillar, and forming a gate to surround an outer circumference of the pillar, wherein the source and the drain may have opposite conductivity types from each other.

These and other features, aspects, and embodiments are described in detail below.

### BRIEF DESCRIPTION OF THE DRAWINGS

The above and other aspects, features and advantages of the in present disclosure will be more clearly understood from the following detailed description taken in conjunction with the accompanying drawings, in which:

FIG. 1 is a cross-sectional view illustrating a method of manufacturing a tunneling transistor having a vertical channel according to an embodiment of the present invention;

FIG. 2 is a cross-sectional view illustrating a method of manufacturing a tunneling transistor having a vertical channel according to an embodiment of the present invention;

FIG. 3 is a cross-sectional view illustrating a method of manufacturing a tunneling transistor having a vertical channel according to an embodiment of the present invention;

FIG. 4 is a cross-sectional view illustrating a method of manufacturing a tunneling transistor having a vertical channel according to an embodiment of the present invention;

FIG. 5 is a cross-sectional view illustrating a variable resistive memory device using a tunneling transistor as a switching device according to an embodiment of the present invention;

FIG. 6 is an energy band diagram illustrating operation characteristics of a tunneling transistor according to an embodiment of the present invention;

FIG. 7 is an energy band diagram illustrating operation characteristics of a tunneling transistor according to an embodiment of the present invention;

FIG. 8 is a cross-sectional′ view illustrating tunneling transistors according to an embodiment of the present invention;

FIG. 9 is a cross-sectional view illustrating tunneling transistors according to an embodiment of the present invention;

FIG. 10 is a cross-sectional view illustrating tunneling transistors according to an embodiment of the present invention;

FIG. 11 is a cross-sectional view illustrating tunneling transistors according to an embodiment of the present invention;

FIG. 12 is a cross-sectional view illustrating tunneling transistors according to an embodiment of the present invention;

FIG. 13 is a schematic circuit diagram illustrating operations of variable resistive memory devices according to an embodiment of the present invention;

FIG. 14 is a schematic circuit diagram illustrating operations of variable resistive memory devices according to an embodiment of the present invention;

FIG. 15 is a schematic circuit diagram illustrating operations of variable resistive memory devices according to an embodiment of the present invention;

FIG. 16 is a schematic circuit diagram illustrating operations of variable resistive memory devices according to an embodiment of the present invention;

FIG. 17 is a block diagram illustrating a microprocessor according to an embodiment of the present invention;

FIG. 18 is a block diagram illustrating a processor according to an embodiment of the present invention; and

FIG. 19 is a block diagram illustrating a system according to an embodiment of the present invention.

### DETAILED DESCRIPTION

Exemplary embodiments and intermediate structures of the present invention will be described in detail with reference to illustrations. Variations in the shapes of the illustrations as a result, for example, of manufacturing techniques and/or tolerances, are to be expected. Additionally, lengths and sizes of layers and regions may be exaggerated for clarity. Like reference numerals in the drawings denote like elements. When a layer is referred to as being “on” another layer or substrate, it can be directly on the substrate or indirectly on the substrate, with intervening layers present. Furthermore, “connected/coupled” refers to one component not only directly coupling another component but also indirectly coupling another component through an intermediate component. In addition, a singular form may include a plural form, and vice versa, so long as it is not specifically mentioned otherwise.

The present invention is described with reference to cross-section and/or plan illustrations of preferred embodiments of the present invention. However, embodiments of the present invention should not be construed as limited to the present invention. Although a few embodiments of the present invention will be shown and described, it will be appreciated by those of ordinary skill in the art that changes may be made in these exemplary embodiments without departing from the principles and spirit of the present invention.

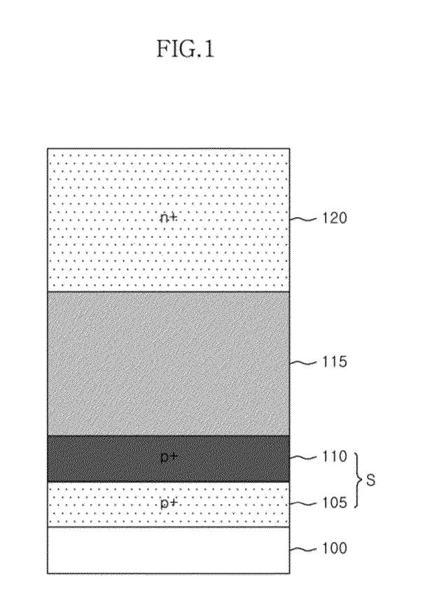

Referring to FIG. 1, a semiconductor substrate is prepared. The semiconductor substrate may be a first semiconductor material layer, for example, a silicon (Si) substrate. The semiconductor substrate 100 may have a conductivity type. A high concentration first conductivity type impurity, for example, a high concentration p-type (i.e., P⁺-type) impurity is implanted into an upper portion of the semiconductor substrate 100 to form a first impurity layer 105. In the embodiment, the first impurity layer 105 is formed through an ion implantation method. However, the first impurity layer 105 may be formed using an epitaxial growth method for single crystal growth or other various deposition methods.

A second impurity layer 110 is formed on the first impurity layer 105. The second impurity layer 110 may be formed of a second semiconductor material layer having a band gap smaller than the first semiconductor material layer (for example, Si) constituting the first impurity layer 105. The second semiconductor material layer may include a silicon germanium (Site) layer, a germanium layer, an indium arsenide (InAs) layer, a gallium antimony (Gab) layer, or an indium antimony (InSb) layer. The second impurity layer 110 may also include a high concentration first conductivity type impurity, for example, a high concentration p-type (i.e., P⁺-type) impurity. The impurities (p⁺) of the second impurity layer 110 may be introduced through an ion implantation method. Alternatively, the second impurity layer 110 may be formed by depositing the second semiconductor material layer containing the high concentration first conductivity type impurity. The second semiconductor material layer may constitute a first junction region, for example, a source S of the transistor together with the first impurity layer 105.

A channel layer 115 and a second junction region layer 120 are formed on the semiconductor substrate 100 in which the first junction region (i.e., the source 5) is formed. The channel layer 115 may be formed of the first semiconductor material layer. The second junction region layer 120 may be formed of the first semiconductor material layer containing a high concentration second conductivity type impurity opposite to the first conductivity type, for example, a high concentration n-type n⁺-type) impurity. The second junction region layer 120 may be formed by depositing a first semiconductor material and implanting the high concentration n-type impurity. Alternatively, the second junction region layer 120 may be formed by depositing the first semiconductor material layer containing a high concentration n-type impurity. The channel layer 115 and the second junction region layer 120 may be formed through an epitaxial growth method.

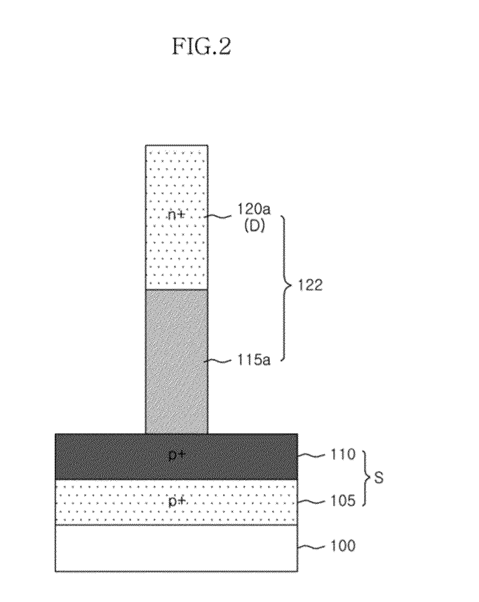

Referring to FIG. 2, predetermined portions of the second junction region layer 120 shown in FIG. 1 and the channel layer 115 shown in FIG. 1, are etched to form a pillar 122. Through the formation of the pillar 122, a drain D of the transistor may be defined. The reference numeral 115a denotes a patterned channel layer. In the embodiment, to implement the tunneling transistor structure, the source S and the drain D may be formed to have opposite conductivity types.

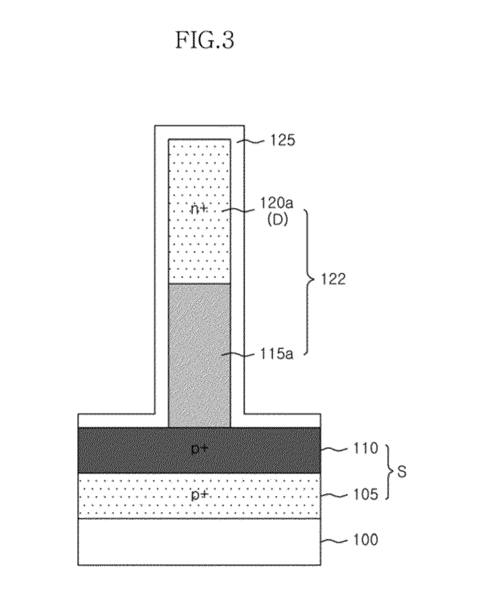

Referring to FIG. 3, a gate insulating layer 125 may be formed on a surface of the pillar 122. The gate insulating layer 125 may be formed through an oxidation method or a deposition method. When the gate insulating layer 125 is formed through the deposition method, the gate insulating layer 125 may include metal oxide such as tantalum oxide (TaO), titanium oxide (TIO), barium titanate (BaTiO), barium zirconate (BaZrO), zirconium oxide (ZrO), hafnium oxide (HfO), lanthanum oxide (LaO), aluminum oxide (AlO), yttrium oxide (YO) or zirconium silicon oxide (ZrSiO), nitride, or a combination.

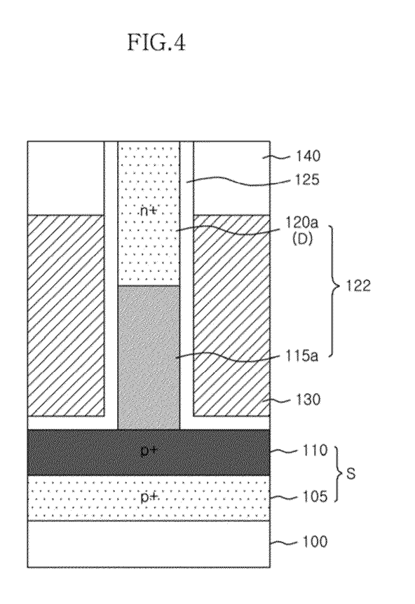

Referring to FIG. 4, a gate 130 may be formed to surround an outer circumference of the pillar 122. The gate 130 may be formed to a lower height than the pillar 122. The gate insulating layer 125 may be positioned between the pillar 122 and the gate 130. The gate 130 may include at least one selected from the group including tungsten (W), copper (C), titanium nitride (TIN), tantalum nitride (Tan tungsten nitride (WN), molybdenum nitride (Mon niobium nitride (NbN), titanium silicon nitride (TiSiN), titanium aluminum nitride (TiAlN), titanium boron nitride (TIBN), zirconium silicon nitride (ZrSiN), tungsten silicon nitride (WSiN) tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), titanium silicide (TiSi), tantalum silicide (TaSi), titanium tungsten (TiW), titanium oxynitride (TiON), titanium aluminum oxynitride (TiAlON), tungsten oxynitride (WON), tantalum oxynitride (TaON), and doped polysilicon. An anisotropic etching method may be used to form the surrounded gate 130.

An interlayer insulating layer 140 is formed on the semiconductor substrate in which the gate 130 is formed. The interlayer insulating layer 140 may be planarized to expose a surface of the pillar 122.

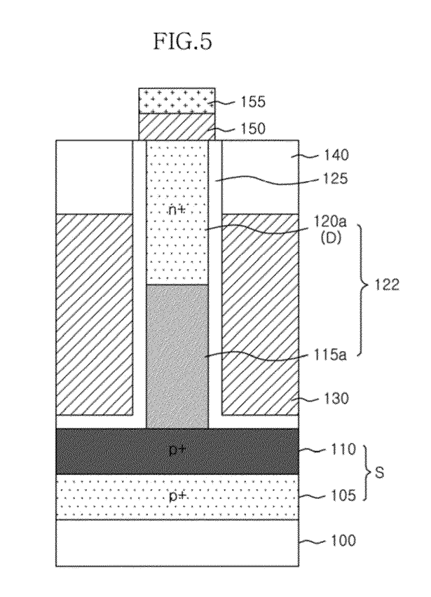

Referring to FIG. 5, a heating electrode 150 and a variable resistive layer 155 may be sequentially formed on a second junction region 120a, the drain D of the variable resistive memory device. The heating electrode 150 and the variable resistive layer 155 may be formed by sequentially stacking the heating electrode 150 and the variable resistive layer 155 on the semiconductor substrate in which the interlayer insulating layer 140 is formed, and patterning the heating electrode 150 and the variable resistive layer 155 in a location where the heating electrode 150 may be electrically coupled to the drain. The heating electrode 150 may include a metal layer, and an ohmic contact layer (not shown) may be interposed between the heating electrode 150 and the variable resistive layer 155.

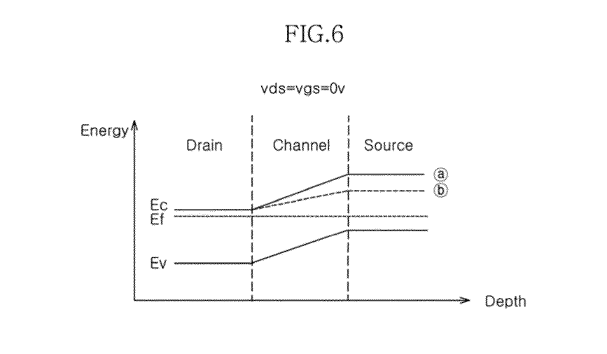

FIG. 6 illustrates an energy band diagram of a tunneling transistor when a bias is not applied.

In FIG. 6, Ev denotes a valance band, Ec denotes a conduction band, and Ef denotes a Fermi level. Since the Fermi level of a p-type impurity and the Fermi level of an n-type impurity are different before a PN junction is made, when an equilibrium state is reached at the PN junction, the valance band Ev and the conduction band Ec at the source having a p-type impurity have a higher energy level than the drain. In FIG. 6, \textcircled{a} denotes a conduction band when the source is formed of the same material (the first semiconductor material layer) as the drain, and \textcircled{b} denotes a conduction band when the source is formed of the second semiconductor material layer having a smaller band gap than the first semiconductor material layer.

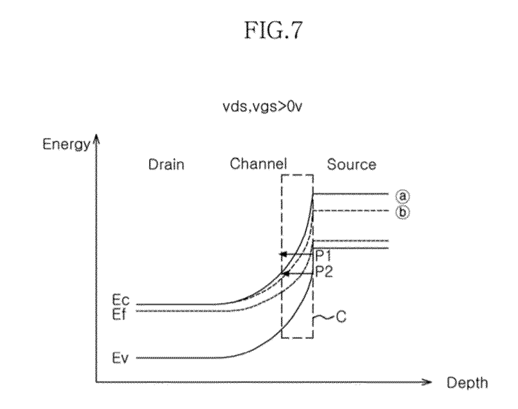

As shown in FIG. 7, when a gate voltage VGS of 0 V or more and a drain voltage (VDS) of 0 V or more are applied, an electric field is applied to a depletion region of a channel by the applied voltages, and thus an energy band curve is bent. Particularly, the energy band of a portion C corresponding to the depletion region of the channel becomes thin, and thus tunneling between the energy bands easily occurs. When the source around the depletion region is formed of a material \textcircled{b} having a relatively low band gap, a large tunneling current may be obtained by a lower voltage.

In FIG. 7, P1 indicates a tunneling path when the source is formed of the second semiconductor material layer having a relatively low band gap according to the embodiment, and P2 indicates a tunneling path when the source is formed of the first semiconductor material layer.

According to the graph, when the junction region (source) is formed of the second semiconductor material layer having a low band gap around the depletion region of the channel, the tunneling current may be improved since a shorter tunneling path is provided.

The source structure of the tunneling transistor in the present invention may exist in various forms.

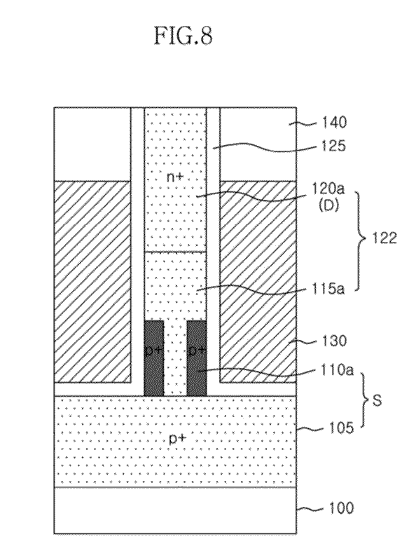

For example, as shown in FIG. 8 a first impurity layer 105 constituting a source S is formed inside a semiconductor substrate 100, a second impurity layer 110a constituting the source S may be formed to constitute a portion of the pillar 122. The second impurity layer 110a may be formed as a pair of patterns spaced part from each other before formation of a channel layer 115a.

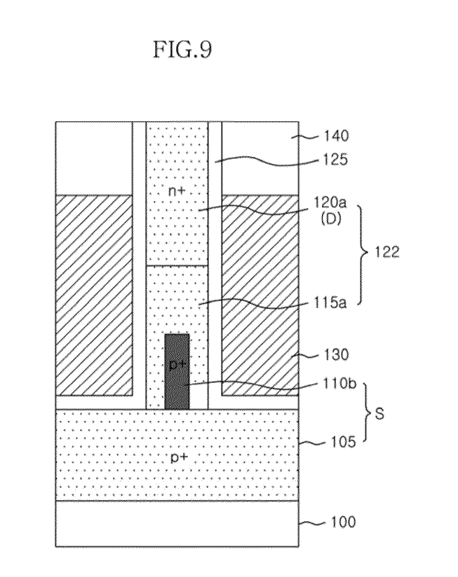

As shown in FIG. 9, a first impurity layer 105 constituting a source S is formed on a semiconductor substrate 100, a second impurity layer 110b constituting the source S may be formed inside the pillar 122. The second impurity layer 110b may be located in a lower core. The second impurity layer 110b may be formed in a single pattern before formation of a channel layer 115a.

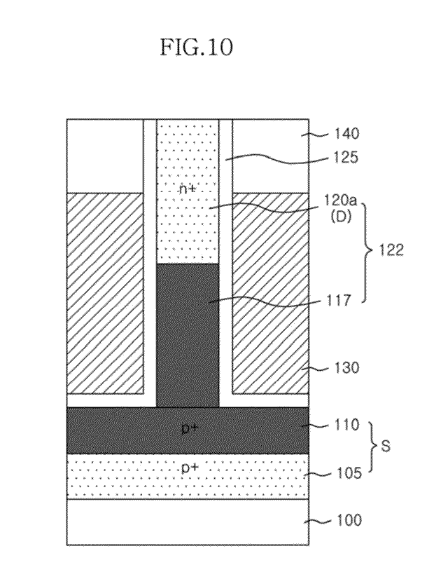

As shown in FIG. 10 a channel layer 117 may constitute a second impurity layer.

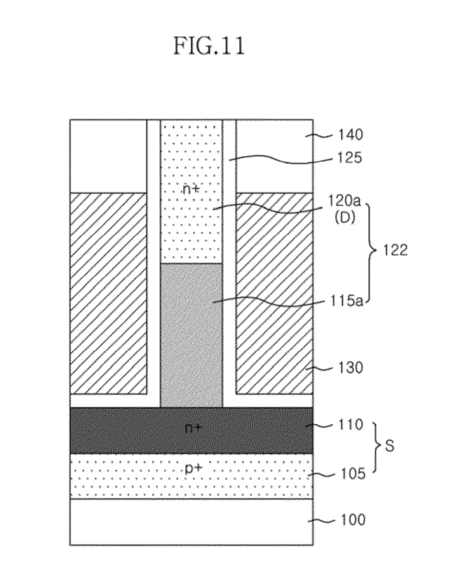

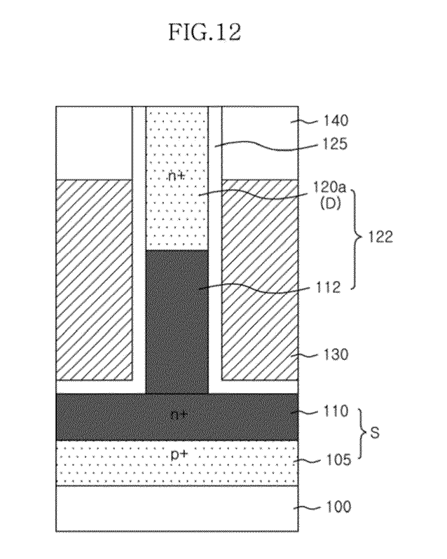

As shown in FIGS. 11 and 12, even when a first junction region S is formed of a material layer doped with the second conductivity type impurity, for example, a high concentration n-type impurity, and a second junction region D is doped with the first conductivity type impurity, for example, a high concentration p-type impurity, the same effect may be obtained.

When the tunneling transistor is applied to a variable resistive memory device, a unit cell of the variable resistive memory device may be driven by the following conditions.

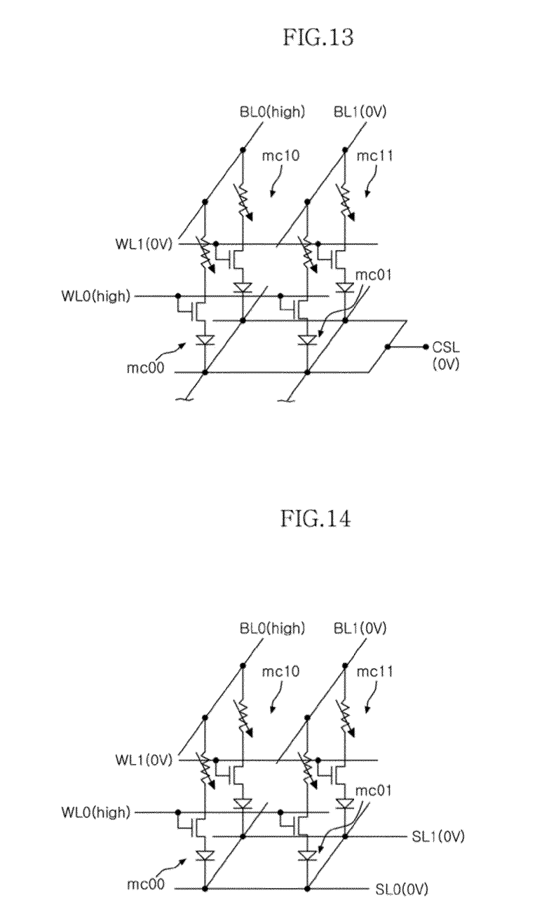

As shown in FIG. 13, the variable resistive memory device may include a plurality of word lines WL0 and WL1, a plurality of bit lines BL0 and BL1, and source lines CSL. The plurality of word lines WL0 and WL1 and the plurality of bit lines BL0 and BL1 may extend in a direction to cross each other, and the source lines may be commonly coupled. A plurality of memory cells mc00, mc01, mc10, and mc11 may be provided at intersection locations of the plurality of word lines WL0 and WL1 and the plurality of bit lines BL0 and BL1. Each of the memory cells mc00, mc01, mc10 and mc11 may include a tunneling transistor coupled to a corresponding word line and a variable resistor coupled between the tunneling transistor and a corresponding bit line. In FIG. 13, the tunneling transistor may be represented with a diode and a MOS transistor coupled in series.

For example, when data of a first memory cell mcOO is read or written, a high voltage (correspond to a write voltage or a read voltage) is applied to a first bit line BL0 coupled to the first memory cell mc00, and 0 (zero) V is applied to the other bit line BL1, a high level voltage is applied to a first word line WL0 of the first memory cell mc00, and 0 V is applied to the other word line WL1. 0 V is also applied to the source lines CSL commonly coupled. Therefore, data on the first bit line BL0 may be stored in the first memory cell mc00 and a memory operation may be realized.

In the embodiment, all the source lines are commonly coupled, but the source lines may be individually divided into source lines SL0 and SL1 as illustrated in FIG. 14. For example, the divided source lines SL0 and SL1 may extend in a direction substantially parallel to the word lines WL0 and WL1. Even when the source lines SL0 and SL1 are individually divided, 0 V may be applied to all divided source lines.

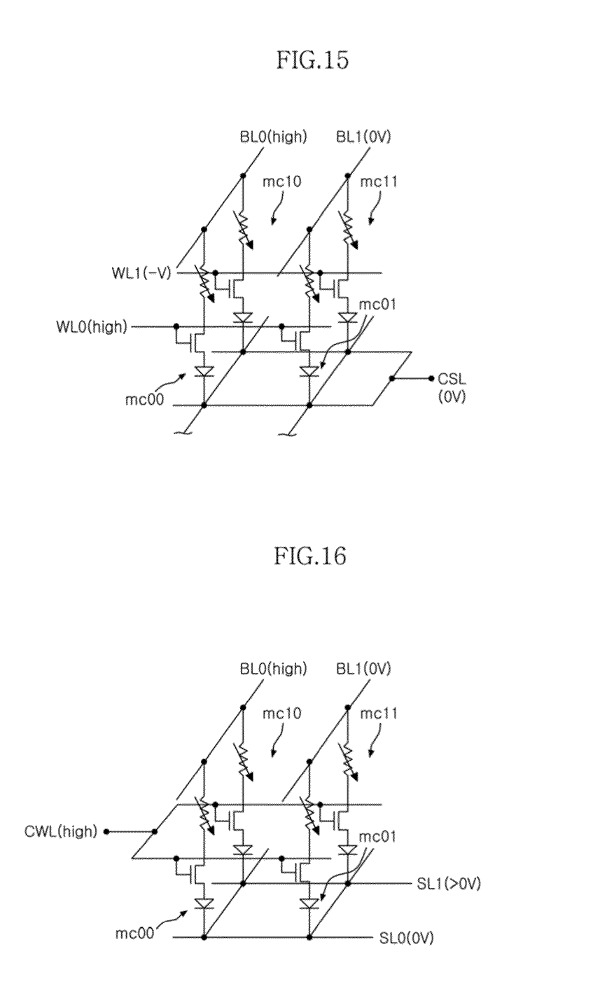

As shown in FIG. 15, a negative voltage (−V) may be applied to a non-selected word line WL1 to reduce leakage current. Even when adjacent word lines are driven, coupling and generation of the leakage current may be prevented.

Referring to FIG. 16, a plurality of word lines are coupled to constitute a common word line CWL. A high voltage may be applied to the common word line CWL. To select a first memory cell mc00, 0 V may be provided to a source line SL0 coupled to the first memory cell mc00, and a voltage of 0 V or more may be applied to other source line SL1. Therefore, memory operations of memory cells other than the first memory cell mc00 may be interrupted.

According to an embodiment of the present invention, to improve tunneling, a semiconductor material having a smaller band gap than the drain may be inserted into or around a tunneling-induced junction region of the tunneling transistor, that is, the source. Since the tunneling transistor has a smaller swing value than a general diode, the tunneling transistor may have current drivability larger than a general diode under the same bias. Further, a semiconductor layer having a smaller band gap than the drain is inserted into or around the source as described above, so that additional tunneling characteristics may be reinforced,

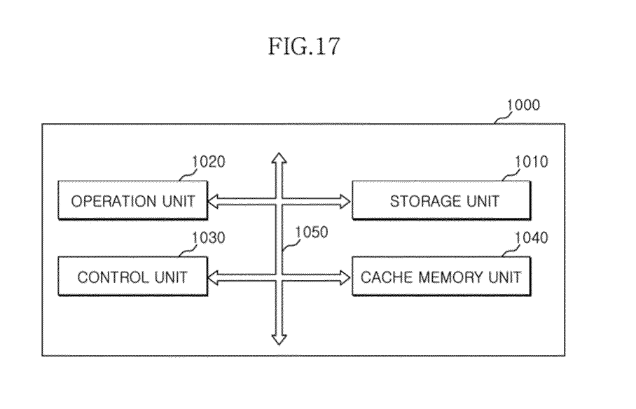

As illustrated in FIG. 17, a microprocessor 1000 to which the semiconductor device according to the embodiment is applied may control and adjust a series of processes, which receive data from various external apparatuses, process the data, and transmit processing results to the external apparatuses. The microprocessor 1000 may include a storage unit 1010, an operation unit 1020, and a control unit 1030. The microprocessor 1000 may be a variety of processing apparatuses, such as a micro processing unit (MPU), a central processing unit (CPU), a graphic processing unit (GPU), a digital signal processor (DSP) or an application processor (AP).

The storage unit 1010 may be a processor register or a register, and the storage unit may be a unit that stores data in the microprocessor 1000 and include a data register, an address register, and a floating point register. The storage unit 1010 may include various registers other than the above-described registers. The storage unit 1010 may temporarily store data to be operated on in the operation unit 1020, resulting data that was processed in the operation unit 1020, and an address in which the data to be operated on is stored.

The storage unit 1010 may include one of the semiconductor devices according to the embodiments of the present invention. The storage unit 1010 including the semiconductor device according to the above-described embodiments may use a tunneling transistor, in which a semiconductor material layer having a low band gap is inserted into or around a source, as a switching device.

The operation unit 1020 may perform an operation in the microprocessor 1000, and perform a variety of four fundamental rules of arithmetic operation or operations, depending on a decryption result of a command in the control unit 1030. The operation unit 1020 may include one or more arithmetic and logic units (ALUs).

The control unit 1030 may receive a signal from the storage unit 1010, the operation unit 1020, or an external apparatus of the microprocessor 1000, may perform extraction or decryption of a command, or input or output control, and may execute a process in a program form.

The microprocessor 1000 according to the embodiments of the present invention may further include a cache memory unit 1040 that may temporarily store data input from an external apparatus or data to be output to an external apparatus, other than the storage unit 1010. The cache memory unit 1040 may exchange data with the storage unit 1010, the operation unit 1020, and the control unit 1030 through a bus interface 1050.

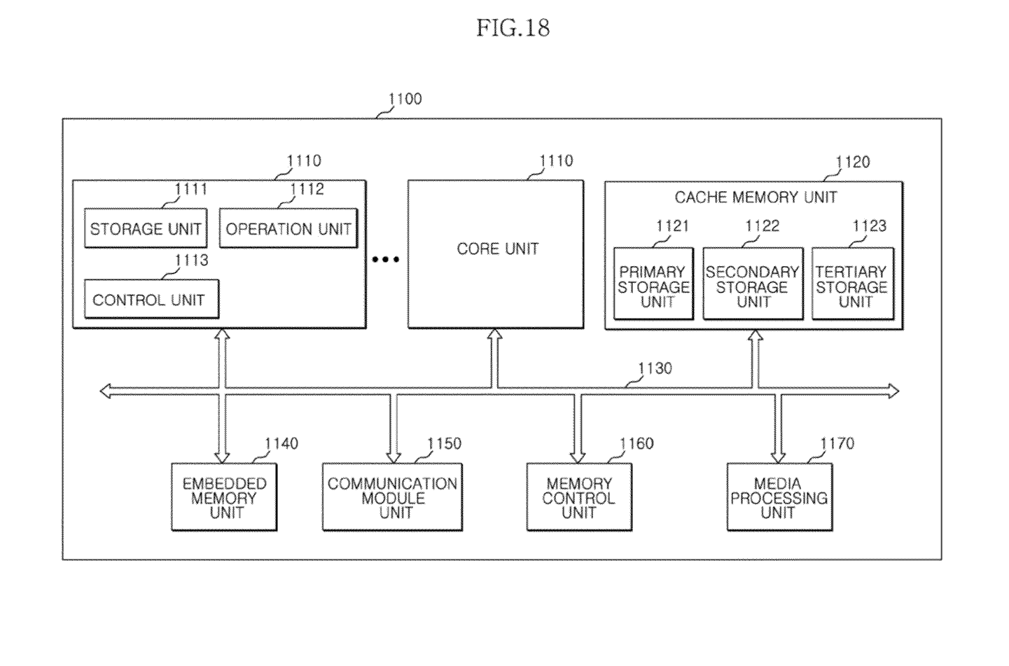

As illustrated in FIG. 18, a processor 1100 in which the semiconductor device according to the embodiment of the present invention is applied may include various functions to implement performance improvement and multifunction, in addition to the functions of the microprocessor that may control and adjust a series of processes, which receive data from various external apparatuses, process the data, and transmit processing results to the external apparatuses. The processor 1100 may include a core unit 1110, a cache memory unit 1120, and a bus interface 1130. The core unit 1110 in an embodiment according to the present invention may perform arithmetic and logic operations on data input from an external apparatus, and include a storage unit 1111, an operation unit 1112, and a control unit 1113. The processor 1100 may be a variety of system on chips (SoCs) such as a multi core processor (MCP), a graphics processing unit (CPU) or an application processor (AP).

The storage unit 1111 may be a processor register or a register, and the storage unit 1111 may be a unit that may store data in the processor 1100 and include a data register, an address register, and a floating point register. The storage unit 1111 may include various registers other than the above-described registers. The storage unit 1111 may temporarily store data to be operated on in the operation unit 1112, resulting data that was processed in the operation unit 1112, and an address in which the data to be operated is stored. The operation unit 1112 may be a unit that may perform an operation in the processor 1100, and perform a variety of four fundamental rules of an arithmetic operation or logic operations depending on a decryption result of a command in the control unit 1113. The operation unit 1112 may include one or more arithmetic and logic units (ALUs). The control unit 1113 receives a signal from the storage unit 1111, the operation unit 1112, or an external apparatus of the processor 1100, performs extraction or decryption of a command, or input or output control, and executes a process in a program form.

The cache memory unit 1120 may temporarily store data to supplement the data processing rate of a low speed external apparatus unlike the high speed core unit 1110. The cache memory unit 1120 may include a primary storage unit 1121, a secondary storage unit 1122, and a tertiary storage unit 1123. In general, the cache memory unit 1120 may include the primary and secondary storage units 1121 and 1122. When a high capacity storage unit is necessary, the cache memory unit 1120 may include the tertiary storage unit 1123. If necessary, the cache memory unit 1120 may include more storage units. That is, the number of storage units included in the cache memory unit 1120 may be changed according to design. Processing rates of data storage and discrimination of the primary, secondary, and tertiary storage units 1121, 1122, and 1123 may be the same or different from each other. When the processing rates of the storage units are different, the processing rate of the primary storage unit is the greatest. One or more of the primary storage unit 1121, the secondary storage unit 1122, and the tertiary storage unit 1123 in the cache memory unit 1200 may include one of the semiconductor devices according to the embodiments of the present invention. The cache memory unit 1120 including the semiconductor device according to the above-described embodiments may use a tunneling transistor, in which a semiconductor material layer having a low band gap is inserted into or around a source, as a switching device. Further, FIG. 18 has illustrated that all the primary, secondary, tertiary storage units 1121, 1122, and 1123 are disposed in the cache memory unit 1120. However, all the primary, secondary, tertiary storage units 1121, 1122, and 1123 in the cache memory unit 1120 may be disposed outside the core unit 1110, and may supplement the difference between the processing rates of the core unit 1110 and an external apparatus. Further, the primary storage unit 1121 of the cache memory unit 1120 may be located in the core unit 1110, and the secondary storage unit 1122 and the tertiary storage unit 1123 may be located outside the core unit 1110 to further compensate for the processing rate.

The bus interface 1130 may couple the core unit 1110 and the cache memory unit 1120 to efficiently transmit data.

The processor 1100 according to the embodiments may include a plurality of core units 1110, and the core units 1110 may share the cache memory unit 1120. The core units 1110 and the cache memory unit 1120 may be coupled through the bus interface 1130. The core units 1110 may have the same configuration as the above-described core unit 1110. When the core units 1110 are provided, the primary storage unit 1121 of the cache memory unit 1120 may be disposed in each of the core units 1110 corresponding to the number of core units 1110, and one secondary storage unit 1122 and one tertiary storage unit 1123 may be disposed outside the core units 1110 so that the core units share the secondary and tertiary storage units through the bus interface 1130. The processing rate of the primary storage unit 1121 may be greater than those of the secondary and tertiary storage units 1122 and 1123.

The processor 1100 according to the embodiments may further include an embedded memory unit 1140 that may store data, a communication module unit 1150 that may transmit and receive data to and from an external apparatus in a wired or a wireless manner, a memory control unit 1160 that may drive an external storage device, and a media processing unit 1170 that may process data processed in the processor 1100 or data input from an external input device and may output a processing result to an external interface device. The processor may further include a plurality of modules other than the above-described components. The additional modules may transmit data to and receive data from the core unit 1110 and the cache memory unit 1120, and transmit and receive data therebetween, through the bus interface 1130.

The embedded memory unit 1140 may include volatile memory as well as nonvolatile memory. The volatile memory may include a dynamic random access memory (DRAM), a mobile DRAM, a static RAM (SRAM), or the like, and the nonvolatile memory may include a read only memory (ROM), a NOR flash memory, a NAND flash memory, a phase-change RAM (PCRAM), a resistive RAM (RRAM), a spin transfer torque RAM (STTRAM), a magnetic RAM (MRAM), or the like. The semiconductor device according to the embodiments may also be applied to the embedded memory unit 1140.

The communication module unit 1150 may include a module coupled to a wired network and a module coupled to a wireless network. The wired network module may include a local area network (LAN), a universal serial bus (USB), Ethernet, power line communication (PLC), or the like, and the wireless network module may include Infrared Data Association (IrDA), Code Division Multiple Access (CDMA), Time Division Multiple Access (TDMA), Frequency Division Multiple Access (TDMA), a wireless LAN, Zigbee, a Ubiquitous Sensor Network (USN), Bluetooth, Radio Frequency Identification (RFID), Long Term Evolution (LTE), Near Field Communication (NFC), Wireless Broadband Internet (Wibro), High Speed Downlink Packet Access (HSDPA), Wideband CDMA (WCDMA), Ultra WideBand (UWB), or the like.

The memory control unit 1160 may manage data transmitted between the processor 1100 and an external storage apparatus that may operate according to a different communication standard from the processor 1100. The memory control unit 1160 may include a variety of memory controllers, or a controller that may control Integrated Device Electronics (IDE), Serial Advanced Technology Attachment (SATA), a Small Computer System Interface (SCSI), a Redundant Array of Independent Disks (RAID), a solid state disk (SSD), External SATA (eSATA), Personal Computer Memory Card International Association (PCMCIA), a USB, a secure digital (SD) card, a mini secure digital (mSD) card, a micro SD card, a secure digital high capacity (SDHC) card, a memory stick card, a smart media (SM) card, a multimedia card (MMC), an embedded MMC (eMMC), a compact flash (CF) card, or the like.

The media processing unit 1170 may process data processed in the processor 1100 or data input from an external input device, and may output a processing result to an external interface device so that the processing result may be transferred in video, sound, or in other ways. The media processing unit 1170 may include a GPU, a DSP, HD audio, a high definition multimedia interface (HDMI) controller, or the like.

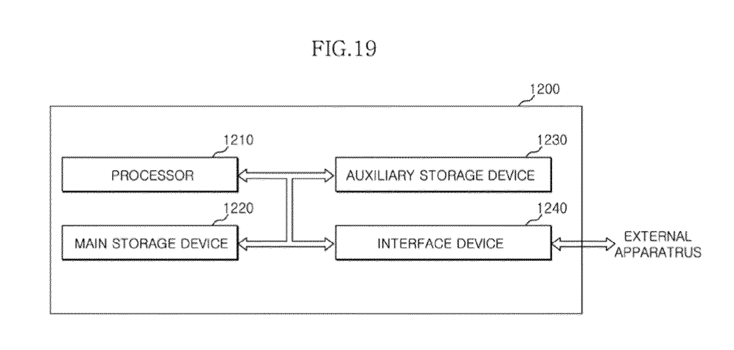

As illustrated in FIG. 19, a system 1200 in which the semiconductor device according to an embodiment of the present invention is applied may be a data processing apparatus. The system 1200 may perform input, processing, output, communication, storage, and the like to perform a series of operations on data, and include a processor 1210, a main storage device 1220, an auxiliary storage device 1230, and an interface device 1240. The system according to the embodiments may be a variety of electronic systems that may operate using a processor, such as a computer, a server, a personal digital assistant (PDA), a portable computer, a web tablet, a wireless phone, a mobile phone, a smart phone, a digital music player, a portable multimedia player (PMP), a camera, a global positioning system (GPS), a video camera, a voice recorder, Telematics, an audio visual (AV) system, or a smart television.

The processor 1210 is a core configuration of the system that may control interpretation of an input command and processing such as an operation and comparison of data stored in the system, and may include a MPU, a CPU, a single/multi core processor, a GPU, an AP, a DSP or the like.

The main storage device 1220 is a storage location that may receive a program or data from the auxiliary storage device 1230 and execute the program or the data. The main storage device 1220 retains the stored content even when powered off, and may include a semiconductor device according to the above-described embodiments. The main storage device 1220 may use a tunneling transistor, in which a semiconductor material layer having a low band gap is inserted into or around a source, as a switching device.

The main storage device 1220 according to the embodiment may further include an SRAM or a DRAM of a volatile memory type in which all contents are erased in power off. Alternatively, the main storage device 1220 may not include a semiconductor device according to the embodiments but may include an SRAM or a DRAM of a volatile memory type in which all contents are erased when powered off.

The auxiliary storage device 1230 may store a program code or data. The auxiliary storage device 1230 may have a lower data processing rate than the main storage device 1220, but may store large amounts of data and include a semiconductor device according to the above-described embodiments. The auxiliary storage unit 1230 may also use a tunneling transistor, in which a semiconductor material layer having a low band gap is inserted into or around a source, as a switching device.

The area of the auxiliary storage device 1230 according to the embodiments of the present invention may be reduced, so that a size of the system 1200 is reduced and portability of the system 1200 is increased. Further, the auxiliary storage device 1230 may further include a data storage system (not shown), such as a magnetic tape or a magnetic disc, a laser disc using light, a magneto-optical disc using magnetism and light, an SSD, a USB memory, a SD card, a mSD card, a micro SD card, a SDHC card, a memory stick card, a SM card, a MMC, an eMMC, or a CF card. Alternatively, the auxiliary storage device 1230 may not include a semiconductor device according to the above-described embodiments but may include a data storage system (not shown), such as a magnetic tape or a magnetic disc using a magnetism, a laser disc using light, a magneto-optical disc using magnetism and light, an SSD, a USB memory, a SD card, a mSD card, a micro SD card, a SDHC card, a memory stick card, a SM card, a MMC, an eMMC, or a CF card.

The interface device 1240 may exchange a command and data of an external apparatus with the system of the embodiment, and may be a keypad, a keyboard, a mouse, a speaker, a microphone, a display, a variety of Human Interface Devices (HIDs), or a communication device. The communication device may include multiple modules such as a module coupled to a wired network and a module coupled to a wireless network. The wired network module may include a LAN, a USB, Ethernet, PLC, or the like, and the wireless network module may include IrDA, CDMA, TDMA, TDMA, a wireless LAN, Zigbee, a USN, Bluetooth, RFID, LTE, NFC, Wibro, HSDPA, WCDMA, UWB, or the like.

The above embodiments of the present invention are illustrative and non-limiting. Various alternatives and equivalents are possible. The invention is not limited by the embodiments described herein. Nor is the invention limited to any specific type of semiconductor device. Other additions, subtractions, or modifications are obvious to one skilled in the art, in view of the present disclosure, and are intended to fall within the scope of the appended claims.

What is claimed is:

1. A tunneling transistor comprising:
a semiconductor substrate having a source formed in an upper region and including a first semiconductor material layer;
a pillar formed on the semiconductor substrate and having a channel layer and a drain sequentially stacked;
a gate formed to surround the pillar; and
a second semiconductor material layer formed between the in source and the channel layer, the second semiconductor material layer having the same conductivity type as the source and having a band gap lower than the first semiconductor material layer,
wherein the source and the drain have opposite conductivity types from each other.

2. The tunneling transistor of claim wherein the first semiconductor material layer includes silicon (Si).

3. The tunneling transistor of claim 2, wherein the second semiconductor material layer includes any one selected from the group including SiGe, Ge, InAs, GaSb, and InSb.

4. The tunneling transistor of claim 1, wherein the second semiconductor material layer forms an edge of a lower portion of the pillar.

5. The tunneling transistor of claim 1, wherein the second semiconductor material layer is located in a lower portion of the pillar.

6. The tunneling transistor of claim 1, wherein the channel layer includes the second semiconductor material layer.

7. A variable resistive memory device comprising:
a semiconductor substrate having a source formed in an upper region and including a first semiconductor material layer;
a pillar formed on a semiconductor substrate and having a channel layer and a drain sequentially stacked, the drain containing dopants having an opposite conductivity type to the source;
a gate formed to surround the pillar;
a second semiconductor material layer formed between the source and the channel layer, the second semiconductor material layer having the same conductivity type as the source and having a band gap lower than the first semiconductor material layer;
a heating electrode formed on the drain; and
a variable resistive layer formed on the heating electrode.

8. The variable resistive memory device of claim 7,
wherein the first semiconductor material layer includes silicon (Si).

9. The variable resistive memory device of claim 8, wherein the second semiconductor material layer includes any one selected from the group including SiGe, Ge, InAs, GaSb, and InSb.

10. The variable resistive memory device of claim 7, wherein the second semiconductor material layer forms an edge of a lower portion of the pillar.

11. The variable resistive memory device of claim 7, wherein the second semiconductor material layer is located in a lower in portion of the pillar.

12. The variable resistive memory device of claim 7, wherein the channel layer includes the second semiconductor material layer.

13. A method of manufacturing a tunneling transistor, the method comprising:
forming a source including a second semiconductor material layer having a band gap smaller than a first semiconductor material layer, on a semiconductor substrate including the first semiconductor material layer;
sequentially stacking a first semiconductor layer for a channel layer and a second semiconductor layer for a drain on the semiconductor substrate;
patterning the first semiconductor layer and the second semiconductor layer to form a pillar that includes the channel layer and the drain;
forming a gate insulating layer on a surface of the pillar; and
forming a gate to surround an outer circumference of the pillar,
wherein the source and the drain have opposite conductivity types from each other.

14. The method of claim 13, wherein the forming of the source includes:
forming the second semiconductor material layer on the semiconductor substrate; and
implanting first conductivity type impurities into the second semiconductor material layer and an upper portion of the semiconductor substrate.

15. The method of claim 14, wherein at least one of the second semiconductor material layer, the second semiconductor layer, and the first semiconductor layer is formed through an epitaxial growth method.

16. The method of claim 15, wherein the first semiconductor material layer includes silicon (Si).

17. The method of claim 16, wherein the second semiconductor material layer includes any one selected from the group including SiGe, Ge, InAs, GaSb, and InSb.
